(19) United States
(12) Patent Application Publication
(10) Pub. No.: US 2006/0260536 A1
(43) Pub. Date: Nov. 23, 2006

(54) Vessel for growing a compound semiconductor single crystal, compound semiconductor single crystal, and process for fabricating the same

(75) Inventors: Michinori Wachi, Hitachi (JP); Shinji Yabuki, Hitachi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: HITACHI CABLE, LTD., Tokyo (JP)

(21) Appl. No.: 11/434,565

(22) Filed: May 16, 2006

(30) Foreign Application Priority Data
May 17, 2005 (JP) 2005-144403
Jan. 19, 2006 (JP) 2006-011035

(51) Int. Cl. C30B 15/00; C30B 21/06; C30B 27/02; C30B 28/10; C30B 30/04

(52) U.S. Cl. 117/13

(57) ABSTRACT

A vessel 1 composed of pyrolitic boron nitride (PBN) for growing a compound semiconductor single crystal is provided with a seed crystal accommodating part 1a, a crystal growth part 1b, and a diameter increasing part 1c, wherein the vessel 1 is composed of pyrolitic boron plate (PBN) and a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel 1. In the vertical crystal growth process, a high quality compound semiconductor single crystal with less crystal defect such as dislocation can be obtained by using the vessel 1 for growing a compound semiconductor single crystal and a method for fabricating a compound semiconductor single crystal using the vessel 1, which can be easily fabricated and by which a shape of melt/crystal interface can be controlled without using complicated equipments.

The present application is based on Japanese Patent Application No. 2005-144403 filed on May 17, 2005 and Japanese Patent Application No. 2006-11035 filed on Jan. 19, 2006, the entire contents of which are incorporated herein by reference.

### BACKGROUND OF THE INVENTION

1. Field of the Invention

The present invention relates to a vessel for growing a compound semiconductor single crystal, a compound semiconductor single crystal and a process for fabricating a compound semiconductor single crystal, and more particularly to a vessel for growing a compound semiconductor single crystal, by which a compound semiconductor single crystal having an excellent quality with less crystal defect such as dislocation, a compound semiconductor single crystal fabricated by using the vessel and a process for fabricating a compound semiconductor single crystal using the vessel.

2. Description of the Related Art

It has been generally known that a compound semiconductor single crystal with less crystal defect such as dislocation can be easily obtained, according to a vertical crystal growth process such as vertical Bridgman process (VB process), since the crystal is grown with smaller temperature gradient compared with a lift process such as Czochralski Process (CZ process). In the vertical crystal growth process, the crystal growth is started from a seed crystal previously disposed at a bottom of the vessel, crystallization (translation) is slowly developed upward, and finally all melt of material is crystallized.

In the vertical Bridgman process, which is one of the vertical crystal growth processes, a crucible made of Pyrolitic Boron Nitride (hereinafter, referred as “PBN”) has been conventionally used as a vessel for crystal growth. The PBN crucible comprises a seed crystal accommodating part for accommodating a seed crystal, a crystal growth part for accommodating a melt of the material, and a diameter increasing part with a diameter increased along a direction toward the crystal growth part. The diameter increasing part may be replaced with a cross sectional area increasing part with a cross sectional area increased along the direction toward the crystal growth part. The diameter increasing part or the cross sectional area increasing part is positioned between the seed crystal accommodating part and the crystal growth part.

The PBN vessel for crystal growth has advantages in that the PBN vessel does not react with material compound at a high temperature during a compound semiconductor single crystal growth process and that the PBN itself has a high purity, and so on. Therefore, the PBN vessel for crystal growth is particularly indispensable for growing a gallium arsenide (GaAs) single crystal, and improvement in characteristics of the PBN vessel is necessary for increasing a repeatability of growth conditions of the compound semiconductor single crystal and increasing a product yield.

It has been generally known that, in the VB process, an essential element for obtaining a single crystal with high repeatability is to control a shape of an interface between the melt and a crystal part, namely a solid/liquid interface. Hereinafter, such a solid/liquid inter face is referred as “melt/crystal interface”. A critical point for controlling the shape of the melt/crystal interface is control of a heat flow in the PBN vessel for crystal growth in the crystal growth process, i.e. the control of a thermal conductivity of the PBN vessel for crystal growth.

In addition, it has been generally know that the PBN has anisotropy in a direction vertical to a thickness direction of a plate and in a direction parallel to the thickness direction of the plate, and that a level of the anisotropy is varied in accordance with variation of manufacturing conditions of the PBN, etc.

Accordingly, in other words, the essential element for obtaining a single crystal with high reproducibility by using the PBN vessel for crystal growth is how to manage and control the level of the anisotropy of the PBN vessel for crystal growth and the difference of the anisotropy level of the PBN vessel for crystal growth due to the difference in the manufacturing conditions.

A relationship between the characteristics of the PBN vessel for crystal growth and the reproducibility of the single crystal is described in JP-A-2004-244232.

JP-A-2004-244232 discloses a vessel for manufacturing a compound semiconductor single crystal, a compound semiconductor single crystal manufactured by using the same, and a compound semiconductor wafer, in which the vessel made of PBN for crystal growth comprises a seed crystal accommodating part, a cross sectional area increasing part and a crystal growth part. In the vessel for crystal growth disclosed by JP-A-2004-244232, the value of the X-ray diffraction integrated intensity ratio {I₍₀₀₂₎/I₍₁₀₀₎} of (002) plane to (100) plane, which is measured at a plane vertical to a thickness direction of the PBN plate constituting the vessel, is set to be lower in the cross sectional area increasing part than in the seed crystal accommodating part and the crystal growth part, in order to increase a possibility of providing all single crystal region from a crystal seeding part to a crystal growth finished part (hereinafter, referred as “All Single”).

Further, JP-A-10-7485 discloses a single crystal growth vessel for compound semiconductor, production of single crystal of compound semiconductor by using the vessel and selection of growth vessel. In the vessel for crystal growth disclosed by JP-A-10-7485, the value of the X-ray diffraction integrated intensity ratio {I₍₀₀₂₎/I₍₁₀₀₎} of (002) plane to (100) plane, measured at a plane vertical to the thickness direction of the PBN plate constituting the vessel, is larger in a crystal growth part than in a diameter increasing part, in order to increase a possibility of providing the “All Single”.

Still further, JP-B-3250409 discloses a vertical type crystal growth process and crystal growth vessel used for the same. In the vessel for crystal growth disclosed by JP-B-3250409, the degree of orientation is gradually varied (i.e. gradually decreased or increased) in a vertical direction, in order to increase the possibility of providing the “All Single”. The degree of orientation is calculated by dividing a value of X-ray diffraction integrated intensity ratio {I₍₀₀₂₎/I₍₁₀₀₎}ₐ in a thickness direction (a-axis direction) of a PBN plate by a value of the X-ray diffraction integrated intensity ratio {I₍₀₀₂₎/I₍₁₀₀₎}_{c} in a length direction (c-axis direction) of the PBN plate.

However, as described above, in the conventional PBN vessels for crystal growth disclosed by JP-A-2004-244232, JP-A-10-7485 and JP-B-3250409, the “All Single” rate (probability) of the resulting compound semiconductor single crystal depends on distribution (fluctuation) of the X-ray diffraction integrated intensity ratio (or the degree of orientation) in a vertical direction of the vessel. Therefore, the single crystal should be fabricated with satisfying the disclosed distribution (fluctuation), so that it relatively involves times and efforts to fabricate the single crystal by using the conventional PBN vessels.

### SUMMARY OF THE INVENTION

Accordingly, it is an object of the invention to provide a vessel for growing a compound semiconductor single crystal, a compound semiconductor single crystal and a process for fabricating a compound semiconductor single crystal, that can be easily fabricated by using the vertical crystal growth process, and in that the shape of the melt/crystal interface can be easily controlled without complicated equipments. According to the invention, it is possible to increase the “All Single” rate and to significantly improve the yield for obtaining an excellent compound semiconductor single crystal with less crystal defect such as dislocation.

The present invention is based on an observation that the All Single rate is significantly influenced by the value of X-ray diffraction integrated intensity ratio across a whole region of the vessel rather than the distribution of the X-ray diffraction integrated intensity ratio in the vertical direction of the vessel disclosed in JP-A-2004-244232.

According to the first feature of the invention, a vessel for growing a compound semiconductor single crystal comprises:

a seed crystal accommodating part for accommodating a seed crystal;

a crystal growth part for accommodating melt of material; and a diameter increasing part with a diameter increased along a direction toward the crystal growth part, the diameter increasing part being disposed between the seed crystal accommodating part and the crystal growth part;

wherein the vessel is composed of a pyrolitic boron nitride plate (PBN) and a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel.

In the vessel for growing a compound semiconductor single crystal, the vessel may be adapted to grow the compound semiconductor single crystal by a vertical crystal growth process.

In the vessel for growing a compound semiconductor single crystal, the vertical crystal growth process may be a vertical Bridgman process (VB process).

In the vessel for growing a compound semiconductor single crystal, the vertical crystal growth process may be a vertical gradient freeze process (VGF process).

In the vessel for growing a compound semiconductor single crystal, the compound semiconductor single crystal may have a crystal diameter of 140 mm or more.

In the vessel for growing a compound semiconductor single crystal, the compound semiconductor single crystal may be a GaAs single crystal.

According to the second feature of the invention, a vessel for growing a compound semiconductor single crystal comprises:

a seed crystal accommodating part for accommodating a seed crystal;

a crystal growth part for accommodating melt of material; and

a cross sectional area increasing part with a cross sectional area increased along a direction toward the crystal growth part, the cross sectional area increasing part being disposed between the seed crystal accommodating part and the crystal growth part;

wherein the vessel is composed of a PBN plate and a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel.

According to the third feature of the invention, a compound semiconductor single crystal, fabricated by using a vessel for compound semiconductor single crystal growth comprises:

a seed crystal accommodating part for accommodating a seed crystal;

a crystal growth part for accommodating melt of material of the compound semiconductor single crystal; and

a diameter increasing part with a diameter increased along a direction toward the crystal growth part, the diameter increasing part being disposed between the seed crystal accommodating part and the crystal growth part;

wherein the vessel is composed of a PBN plate and a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel.

According to the fourth feature of the invention, a process for fabricating a compound semiconductor single crystal by using a vessel, composed of a PBN plate, comprises a seed crystal accommodating part for accommodating a seed crystal, a crystal growth part for accommodating melt of material, and a diameter increasing part with a diameter increased along a direction toward the crystal growth part, the diameter increasing part being disposed between the seed crystal accommodating part and the crystal growth part, wherein a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel.

According to the fifth feature of the invention, a process for fabricating a compound semiconductor single crystal comprises steps of:

preparing a vessel composed of a PBN plate;

disposing a seed crystal in the vessel;

pouring a melt of a material, a dopant and a liquid encapsulant in the vessel;

setting the vessel disposed on a support in a furnace;

filling an inert gas in the furnace after vacuuming;

melting the material by heating

elevating a temperature of the furnace for seeding while keeping a temperature gradient of a melt/crystal interface at a constant value; and

descending the vessel at a predetermined rate after seeding;

wherein said vessel comprises a seed crystal accommodating part for accommodating a seed crystal, a crystal growth part for accommodating melt of material, and a diameter increasing part with a diameter increased along a direction toward the crystal growth part, the diameter increasing part being disposed between the seed crystal accommodating part and the crystal growth part, and a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel.

According to the invention, it is possible to provide the vessel for growing a compound semiconductor single crystal, the compound semiconductor single crystal and the process for fabricating a compound semiconductor single crystal, in that the shape of the melt/crystal interface can be easily controlled without the complicated equipments. Accordingly, it is possible to increase the “All Single” rate and to significantly improve the yield for obtaining the excellent compound semiconductor single crystal with less crystal defect such as dislocation.

### BRIEF DESCRIPTION OF THE DRAWINGS

Preferred embodiments present invention will be described in conjunction with appended drawings, wherein:

FIG. 1 is a cross sectional view showing a vessel for growing a compound semiconductor single crystal in a preferred embodiment according to the invention;

FIG. 2 is a schematic diagram showing a compound semiconductor single crystal growth furnace using the vessel for growing a compound semiconductor single crystal in the preferred embodiment according to the invention; and

FIG. 3 is a graph showing a relationship (experimental result) between the X-ray diffraction integrated intensity ratio and the All Single rate (probability).

### DESCRIPTION OF THE PREFERRED EMBODIMENT

Preferred embodiment according to the present invention will be explained in detail hereinafter by referring to the appended drawings.

(Structure of a Vessel for Growing a Compound Semiconductor Single Crystal)

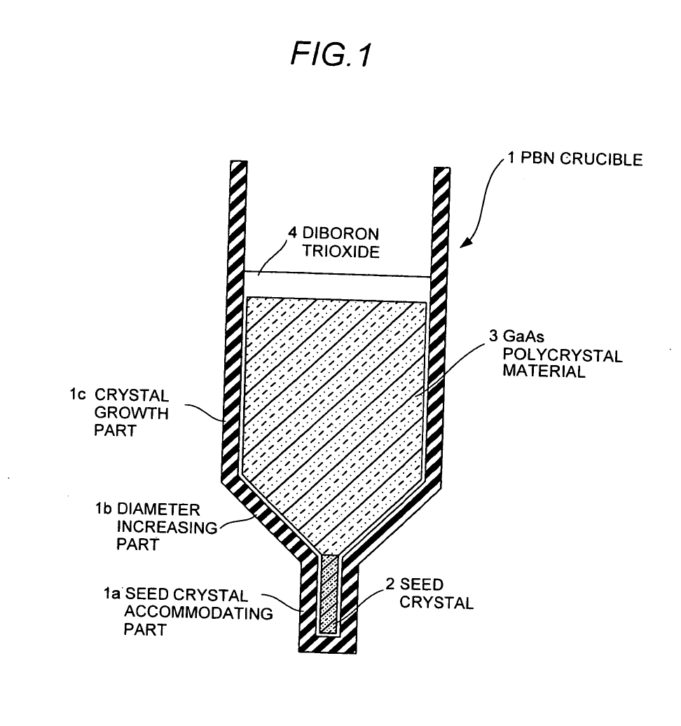

FIG. 1 is a cross sectional view of the vessel for growing a compound semiconductor single crystal in the preferred embodiment according to the invention. A crucible 1 composed of a PBN plate, which is a vessel for growing a compound semiconductor single crystal, comprises a seed crystal accommodating part 1a for accommodating a seed crystal 2, a crystal growth part 1c for accommodating melt of material such as GaAs polycrystal material 3 and liquid encapsulant such as diboron trioxide 4, and a diameter increasing part 1b with a diameter increased along a direction toward the crystal growth part 1c, which is disposed between the seed crystal accommodating part 1a and the crystal growth part 1c. The diameter increasing part 1b may be replaced with a cross sectional area increasing part 1b with a cross sectional area increased along the direction toward the crystal growth part 1c.

In the PBN crucible 1, the seed crystal accommodating part 1a has a circular cross section, and the crystal growth part 1c has a circular cross section. The cross sectional area of the seed crystal accommodating part 1a is smaller than that of the crystal growth part 1c, which is approximately constant. Generally, the diameter increasing part 1b has such configuration that the diameter of the diameter increasing part 1b slowly increases from a diameter of the seed crystal accommodating part 1a to a diameter of the seed crystal growth part 1c. When the cross sectional area increasing part 1b is used in place of the diameter increasing part 1b, the cross sectional area increasing part 1b has such configuration that the cross sectional area of the diameter increasing part 1b slowly increases from a cross sectional area of the seed crystal accommodating part 1a to a cross sectional area of the seed crystal growth part 1c.

Further, the PBN crucible 1 is a vessel for growing a compound semiconductor single crystal by using the vertical crystal growth process.

The vertical crystal growth process includes, for example, a vertical Bridgman process (VB process) in which a growth vessel descends relatively to grow a crystal, a vertical gradient freeze process (VGF process) in which the crystal is grown only by temperature fall, a crystal growth process by controlling As pressure, and a crystal growth process in which a melt surface is covered with B₂O₃ in an atmosphere of inert gas to prevent the vaporization of As.

As a compound semiconductor single crystal to be grown, GaAs single crystal as well as other compound semiconductor single crystals such as InP, GaP, InAs can be applied. The compound semiconductor single crystal such as GaAs, InP, GaP, and InAs is preferably used for growing a large-sized crystal with a crystal diameter of 140 mm or more, in particular, GaAs, InP, GaP, and InAs are suitable for growing a compound semiconductor single crystal growth with a crystal diameter of 140 mm to 160 mm.

In addition, the PBN crucible 1 is characterized by that a value of the X-ray diffraction integrated intensity ratio {I₍₀₀₂₎/I₍₁₀₀₎} of (002) plane to (100) plane, measured at a plane vertical to the thickness direction of the PBN plate is 50 or more across a whole region of the PBN crucible 1, namely all over the PBN crucible 1. The above conditions are satisfied when a part having a minimum value of the X-ray diffraction integrated intensity ratio {I₍₀₀₂₎/I₍₁₀₀₎} in the PBN plate constituting the PBN crucible 1 has a value of 50 or more. In other words, it is not required that the value of the X-ray diffraction integrated intensity ratio {I₍₀₀₂₎/I₍₁₀₀₎} is constant all over the PBN crucible 1. However, fluctuation of the value of the X-ray diffraction integrated intensity ratio {I₍₀₀₂₎/I₍₁₀₀₎} is preferably 100 or less, more preferably 50 or less, and most preferably 20 or less. When the value of the X-ray diffraction integrated intensity ratio {I₍₀₀₂₎/I₍₁₀₀₎} is more than 50, the All Single rate tends to increase in accordance with the increase of the minimum value in the PBN crucible 1.

Upper limit of the X-ray diffraction integrated intensity ratio is not limited, however, preferably 1000 or less, and more preferably 500 or less.

The X-ray diffraction analysis for calculating the X-ray diffraction integrated intensity ratio is conducted under following measurement conditions.

<Measurement Conditions>

X-ray source: CuKα ray

Voltage/Current: 40 kV/30 mA

Slit: DS 1, RS 0.3, SS 1

Scanning speed: 10/min

Scanning amplitude (2θ):
from 24° to 28° for the (002) plane
from 40° to 50° for the (100) plane

The PBN crucible 1 may be fabricated, for example, by making high purity boron trichloride gas or high purity boron trifluoride gas react with high purity ammonia gas under a reduced pressure at a high temperature to precipitate a reaction product on a carbon substrate. The PBN crucible 1 which satisfies the above conditions can be fabricated by adjusting a reaction pressure and a reaction temperature.

In more detail, the PBN crucible 1 may be fabricated by reacting the high purity boron halogenide gas such as boron trichloride gas (BCl₃) and the high purity ammonia gas (NH₃) in a proportion of 1:3 under the reduced pressure at the high temperature to precipitate the reaction product, for example, on the carbon substrate. Generally, the reduced pressure is within a range of 1 to 10 Torr, and the high temperature is within a range of 1800 to 1900° C. The X-ray diffraction integrated intensity ratio {I₍₀₀₂₎/I₍₁₀₀₎} of the PBN crucible 1 fabricated under this condition becomes normally 50 or less. The PBN crucible 1 having the X-ray diffraction integrated intensity ratio {I₍₀₀₂₎/I₍₁₀₀₎} of 50 or more according to the present invention is fabricated under a pressure lower than 1 Torr and at a temperature higher than 1900° C. So as to increase the value of the X-ray diffraction integrated intensity ratio {I₍₀₀₂₎/I₍₁₀₀₎} of the PBN crucible 1, it is preferable to reduce the pressure and to elevate the growth temperature for the fabrication process of the PBN crucible 1. The PBN crucible 1 used in this preferred embodiment is fabricated under pressure of 0.1 to 1 Torr and at temperature of 1900 to 1950° C., such that the value of the X-ray diffraction integrated intensity ratio {I₍₀₀₂₎/I₍₁₀₀₎} is more than 50.

(Structure of the Compound Semiconductor Single Crystal)

In the compound semiconductor single crystal of GaAs, etc. fabricated by using the vessel (PBN crucible 1) for growing a compound semiconductor single crystal as described above, the All Single rate is significantly high, i.e. the rate is 80% or more. In addition, the compound semiconductor single crystal thus obtained is a high quality compound semiconductor single crystal with less crystal defect such as dislocation, and can be used as a compound semiconductor wafer with excellent quality.

(Process for Fabricating the Compound Semiconductor Single Crystal)

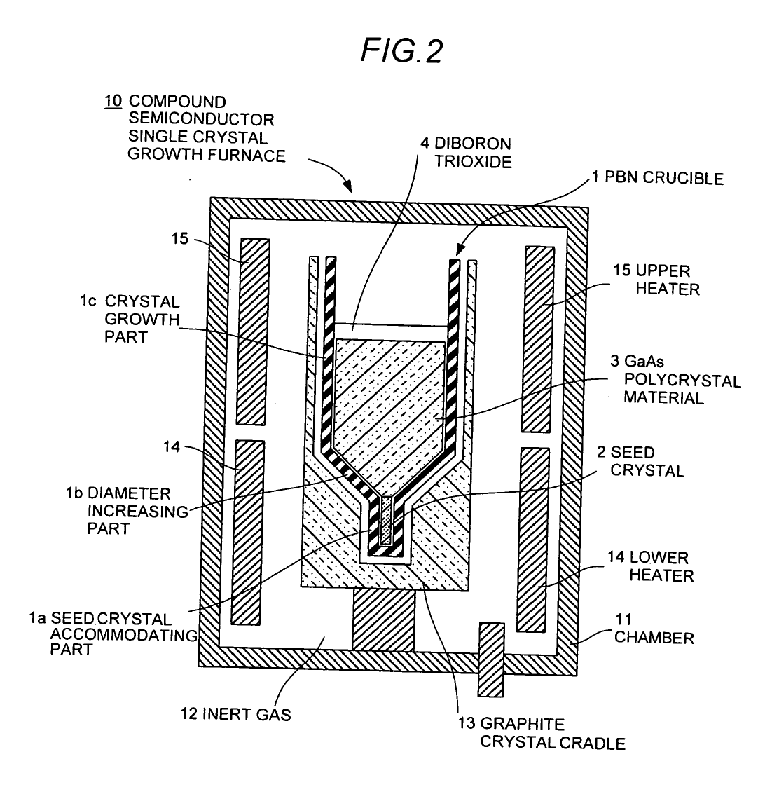

FIG. 2 is a schematic diagram showing a compound semiconductor single crystal growth furnace using the vessel for growing a compound semiconductor single crystal in the preferred embodiment according to the invention.

A compound semiconductor single crystal growth furnace 10 is an apparatus for fabricating a compound semiconductor single crystal. The compound semiconductor single crystal growth furnace 10 comprises a PBN crucible 1 for accommodating a melt, a chamber 11, an inert gas 12 filled in the chamber 11, a crystal cradle (crucible support) 13 made of graphite for accommodating the PBN crucible 1, lower heaters 14 made of graphite, and upper heaters 15 made of graphite. The melt accommodated in the PBN crucible 1 is heated by the lower and upper heaters 14, 15 in the atmosphere of the inert gas 12. The PBN crucible 1 comprises a seed crystal accommodating part 1a, a diameter increasing part 1b and a crystal growth part 1c.

Firstly, the melt of material such as GaAs polycrystal material 3 is accommodated in the PBN crucible 1. The crystal growth is started from the seed crystal 2 which is previously disposed at a bottom of the PBN crucible 1. The crystallization is slowly developed upward, and finally all the melt of the material is solidified to provide the compound semiconductor single crystal such as the GaAs single crystal.

To be more concrete, in the PBN crucible 1, the seed crystal 2 is accommodated in the seed crystal accommodating part 1a, and the GaAs polycrystal material 3, Si as n-type dopant, and diboron trioxide (B₂O₃) 4 as liquid encapsulant are provided on the seed crystal 2. Next, the graphite crystal cradle 13 and the PBN crucible 1 disposed on the graphite crystal cradle 13 are set in the growth furnace 10. After setting the graphite crystal cradle 13 and the PBN crucible 1, the growth furnace 10 is vacuumed and substituted with the inert gas 12, and the furnace temperature (temperature inside the furnace) is elevated by the lower heater 14 and the upper heater 15. Then, only the GaAs polycrystal material 3 is completely melt such that temperature gradient of the melt/crystal interface is set to be a predetermined value, for example, about 5° C./cm. While keeping the temperature gradient of the melt/crystal interface at the predetermined value (e.g. about 5° C./cm) , the furnace temperature is elevated such that a dissolution rate of the seed crystal 2 is 3.0 mm/hr, then seeding process is conducted. After the seeding process, the PBN crucible 1 is moved downward at a predetermined rate, for example, 2.0 mm/hr to fabricate the GaAs single crystal.

### EFFECT OF THE PREFERRED EMBODIMENT

In the preferred embodiment according to the invention, the minimum value of the X-ray diffraction integrated intensity ratio {I₍₀₀₂₎/I₍₁₀₀₎} of the PBN crucible 1 becomes 50 or more. As a result, the All Single rate can be significantly increased. Particularly, in the growth of a compound semiconductor single crystal with a crystal diameter of 140 mm or more, the All Single rate can be increased to be 80% or more.

Further, when the fluctuation of the value of the X-ray diffraction integrated intensity ratio {I₍₀₀₂₎/I₍₁₀₀₎} is 100 or less, 50 or less, and 20 or less, the All Single rate can be further improved by about 1%, about 2%, and about 4%, respectively.

### EMBODIMENTS

### COMPARATIVE EXAMPLE

In a comparative example, GaAs single crystal (crystal diameter of 150 mm), which is a kind of a compound semiconductor, is grown by the vertical Bridgman process using a conventional vessel for crystal growth.

As the vessel for crystal growth, a crucible made of PBN for crystal growth comprising a crystal growth part with a diameter of 150 mm and a length of 200 mm, a seed crystal accommodating part with a diameter of 10 mm, and a diameter increasing part in which a diameter is slowly increased from 10 mm to 150 mm is prepared. At this time, a value of the X-ray diffraction integrated intensity ratio {I₍₀₀₂₎/I₍₁₀₀₎} of (002) plane to (100) plane, measured at a plane vertical to the thickness direction of the PBN plate constituting the vessel for crystal growth, is not determined.

Firstly, the GaAs seed crystal is previously interposed in a bottom of the vessel for crystal growth, and 12,000 g of GaAs polycrystal material and 500 g of B₂O₃ liquid encapsulant are poured into the vessel for crystal growth. The vessel for crystal growth is installed in a pressure vessel, an atmosphere in the pressure vessel is substituted for inert gas, heaters are supplied with power, and the GaAs polycrystal material is melted by heaters, so that a GaAs polycrystal material melt layer and a B₂O₃ liquid encapsulant layer are provided. Then the seeding process is conducted. Subsequently, the crystal is grown by using the vertical Bridgman process in which a temperature gradient of 5° C./cm is set and the vessel for crystal growth is descended at the rate of 5 mm/hr.

According to the manner described above, the crystal growth process was conducted for 50 times. As a result, the All Single rate was 40%.

In addition, it has been known that there is a strong correlation between a single crystal yield of the compound semiconductor single crystal and the shape of the melt/crystal interface. When the shape of the melt/crystal interface is concave with respect to the melt (liquid), regardless the total or a part of the crystal growth process, the crystals defect such as lineage or sub-boundary may be easily integrated and the resulting crystal may easily become polycrystal. Naturally, the single crystal yield will be reduced. Therefore, an important factor to improve the single crystal yield is to keep the shape of the melt/crystal interface convex with respect to the melt during the total of the crystal growth process.

Accordingly, the GaAs single crystal fabricated by the above crystal growth process is taken out from the vessel for crystal growth and cut in a direction that is horizontal to a growth direction, and lapping treatment and polishing treatment are conducted for a cutting plane of the GaAs single crystal to provide a mirror surface. Finally, AB etching process is conducted for the mirror surface to expose a striation, namely the shape of the melt/crystal interface. In the comparative example, there was observed that a degree of convex of the melt/crystal interface with respect to the melt is low during the total of the crystal growth process and that a concave part with respect to the melt was generated.

### First Embodiment

In a first embodiment, a crucible composed of a PBN plate for crystal growth having a configuration similar to that of the comparative example is prepared. Namely, the PBN crucible comprises a crystal growth part with a diameter of 150 mm and a length of 200 mm, a seed crystal accommodating part with a diameter of 10 mm, and a diameter increasing part in which a diameter is slowly increased from 10 mm to 150 mm. Herein, a value of the X-ray diffraction integrated intensity ratio {I₍₀₀₂₎/I₍₁₀₀₎} of (002) plane to (100) plane, measured at a plane vertical to the thickness direction of the PBN plate constituting the vessel for crystal growth, is more than 50 across a whole region of the vessel.

Then, the crystal growth process was conducted for 50 times according to the same manner as that of the comparative example. As a result, the All Single rate in the GaAs was 80%.

Further, according to the same manner as that of the comparative example, the shape of the melt/crystal interface was observed. It was observed that the melt/crystal interface was convex with respect to the melt during the total of the crystal growth process.

### Second Embodiment

In a second embodiment, a plurality of PBN crucibles for crystal growth each having a configuration similar to those of the comparative example and the first embodiment are prepared. In the respective PBN crucibles, a value (minimum value) of the X-ray diffraction integrated intensity ratio {I(₀₀₂₎/I₍₁₀₀₎} of (002) plane to (100) plane, measured at a plane vertical to the thickness direction of the PBN plate constituting the vessel for crystal growth is from 20 to 70. The minimum value is varied by five (i.e. 20, 25, 30, 35 . . . 65, and 70) for the respective PBN crucibles.

Then, the crystal growth process of GaAs was conducted for 5 times according to the same manner as that of the comparative example for each of the PBN crucibles.

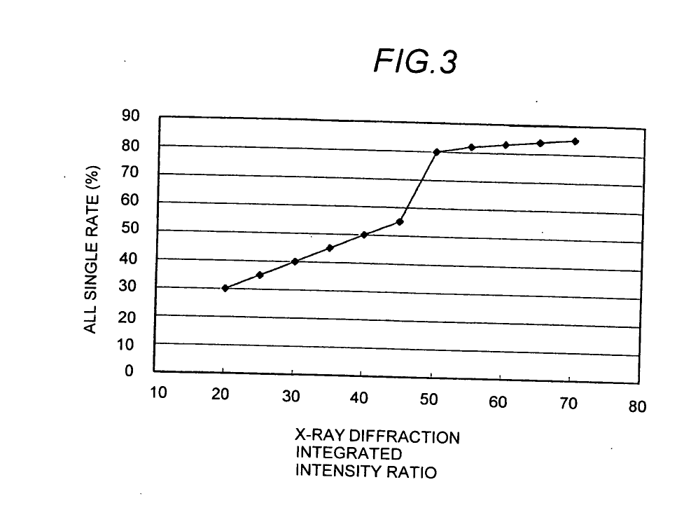

FIG. 3 is a graph showing a relationship between the X-ray diffraction integrated intensity ratio and the All Single rate based on experimental results of the second embodiment, in which a horizontal axis indicates the minimum value of the X-ray diffraction integrated intensity ratio in the PBN crucible and a vertical axis indicates the All Single rate.

As shown in FIG. 3, there is a positive correlation between the X-ray diffraction integrated intensity ratio and the All Single rate. It was understood that the All Single rate is largely increased, e.g. 80% or more, when the X-ray diffraction integrated intensity ratio (the minimum value) is more than 50.

Although the invention has been described with respect to specific embodiment for complete and clear disclosure, the appended claims are not to be thus limited but are to be construed as embodying all modification and alternative constructions that may be occurred to one skilled in the art which fairly fall within the basic teaching herein set forth.

What is claimed is:

1. A vessel for growing a compound semiconductor single crystal comprising:
a seed crystal accommodating part for accommodating a seed crystal;
a crystal growth part for accommodating melt of material; and
a diameter increasing part with a diameter increased along a direction toward the crystal growth part, the diameter increasing part being disposed between the seed crystal accommodating part and the crystal growth part;
wherein the vessel is composed of a pyrolitic boron nitride (PBN) plate and a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel.

2. The vessel for growing a compound semiconductor single crystal, according to claim 1, wherein:
the vessel is adapted to grow the compound semiconductor single crystal by a vertical crystal growth process.

3. The vessel for growing a compound semiconductor single crystal, according to claim 2, wherein:
the vertical crystal growth process is a vertical Bridgman process (VB process).

4. The vessel for growing a compound semiconductor single crystal, according to claim 2, wherein:
the vertical crystal growth process is a vertical gradient freeze process (VGF process).

5. The vessel for growing a compound semiconductor single crystal, according to claim 1, wherein:
the compound semiconductor single crystal has a crystal diameter of 140 mm or more.

6. The vessel for growing a compound semiconductor single crystal, according to claim 1, wherein:
the compound semiconductor single crystal is a GaAs single crystal.

7. A vessel for growing a compound semiconductor single crystal comprising:
a seed crystal accommodating part for accommodating a seed crystal;
a crystal growth part for accommodating melt of material; and
a cross sectional area increasing part with a cross sectional area increased along a direction toward the crystal growth part, the cross sectional area increasing part being disposed between the seed crystal accommodating part and the crystal growth part;
wherein the vessel is composed of a PBN plate and a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel.

8. A compound semiconductor single crystal, fabricated by using a vessel for compound semiconductor single crystal growth comprising:
a seed crystal accommodating part for accommodating a seed crystal;
a crystal growth part for accommodating melt of material of the compound semiconductor single crystal; and
a diameter increasing part with a diameter increased along a direction toward the crystal growth part, the diameter increasing part being disposed between the seed crystal accommodating part and the crystal growth part;
wherein the vessel is composed of a PBN plate and a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel.

9. A process for fabricating a compound semiconductor single crystal by using a vessel, composed of a PBN plate, comprising a seed crystal accommodating part for accommodating a seed crystal, a crystal growth part for accommodating melt of material, and a diameter increasing part with a diameter increased along a direction toward the crystal growth part, the diameter increasing part being disposed between the seed crystal accommodating part and the crystal growth part, wherein a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel.

10. A process for fabricating a compound semiconductor single crystal comprising steps of:
preparing a vessel composed of a PBN plate;
disposing a seed crystal in the vessel;
pouring a melt of a material, a dopant and a liquid encapsulant in the vessel;
setting the vessel disposed on a support in a furnace;
filling an inert gas in the furnace after vacuuming;
melting the material by heating
elevating a temperature of the furnace for seeding while keeping a temperature gradient of a melt/crystal interface at a constant value; and
descending the vessel at a predetermined rate after seeding;
wherein said vessel comprises a seed crystal accommodating part for accommodating a seed crystal, a crystal growth part for accommodating melt of material, and a diameter increasing part with a diameter increased along a direction toward the crystal growth part, the diameter increasing part being disposed between the seed crystal accommodating part and the crystal growth part, and a value of X-ray diffraction integrated intensity ratio {I₍₀₀₂₎/I₍₁₀₀₎} of (002) plane to (100) plane, measured at a plane vertical to a thickness direction of the PBN plate is more than 50 across a whole region of the vessel.
